(19) United States
(12) Patent Application Publication
(10) Pub. No.: US 2009/0085617 A1
(43) Pub. Date: Apr. 2, 2009

(54) RAMP VOLTAGE CIRCUIT

(75) Inventor: Jose Luis Ceballos, Villach (AT)

Correspondence Address: INFINEON TECHNOLOGIES AG;Patent Department, MUC 11.1.507, P.O. Box 221644, Munich, 80506, DE

(73) Assignee: INFINEON TECHNOLOGIES AG, Muenchen (DE)

(21) Appl. No.: 11/862,210

(22) Filed: Sep. 27, 2007

(51) Int. Cl. H03K 4/06

(52) U.S. Cl. 327/131

(57) ABSTRACT

Implementations related to ramp voltage generating circuits and systems implementing the same are presented herein.

### BACKGROUND

Digital image display devices are well known and are based upon a variety of technologies such as cathode ray tubes, liquid crystal and solid-state light emitters such as Organic Light Emitting Diodes (OLEDs). In a common OLED display device a pixel includes red, green, and blue colored OLEDs. By combining the illumination from each of these three OLEDs in an additive color system, a full-color display having a wide variety of colors can be achieved.

OLEDs may be used to generate color directly using organic materials that are doped to emit energy in desired portions of the electromagnetic spectrum. However, the known red and blue emissive materials are not particularly power efficient. In fact, broad bandwidth (white appearing) materials are known that have power efficiencies that are high enough by comparison to narrow bandwidth materials to produce a comparably power efficient OLED display by placing color filters over a broad bandwidth emissive material. Therefore, it is known in the art to produce OLED displays by building a display using an array of white-emitting OLEDs and placing color filters over the OLEDs to achieve red, green and blue light emitting elements in each pixel. Nonetheless, improved OLED display power efficiency continues to be a sought after attribute.

### BRIEF DESCRIPTION OF THE DRAWINGS

The detailed description is described with reference to the accompanying figures. In the figures, the left-most digit(s) of a reference number identifies the figure in which the reference number first appears. The use of the same reference numbers in different figures indicates similar or identical items.

FIG. 1 is a diagram illustrating a pixel arrangement that may be incorporated in a display device. The sixteen pixels illustrated in the figure is by way of example only. Any number of pixels may be incorporated in a display device.

FIG. 2 illustrates a larger view of one of the pixels illustrated in FIG. 1. The FIG. 2 shows that the pixels may also receive a ramp voltage that may be used to regulate the luminance level of the pixels.

FIG. 3 illustrates an exemplary ramp voltage generating circuit. The exemplary ramp voltage generating circuits may be used in conjunction with the implementations illustrated in FIGS. 1 and 2.

FIG. 4 is a signal diagram that may be used to describe the operation of the generating circuit illustrated in FIG. 3.

FIG. 5 illustrates a flow diagram that includes a number of operations enabling the production of a ramp voltage.

FIG. 6 is a block diagram of a general purpose computing system operable to support and make use of a ramp voltage generating circuit. An exemplary implementation of a ramp voltage generating circuit is shown in FIG. 3.

### DETAILED DESCRIPTION

### Overview

One implementation provides a ramp voltage generating circuit that may be used in connection with a display device. The display device may incorporate a plurality of pixels that may produce varying luminance levels. The ramp voltage generating circuit may receive a pulsed control signal. The pulsed control signal toggles two switches. When the switches are toggled in a first state, a ramp voltage is generated. The ramp voltage may have a rapid leading edge rise time. When the switches are toggled in a second state, the ramp voltage has a ramped down signal portion that is dictated by way of capacitor discharge. In one implementation, discharged capacitor current is sourced through an (N-channel Metal-oxide Semiconductor) NMOS transistor associated with an operational transconductance amplifier (OTA). The discharging capacitor may be associated with a pixel driver circuit. In another implementation, at least one of the two switches is a (P-channel Metal-oxide Semiconductor) PMOS transistor. This PMOS transistor may also be referred to as a PMOS switch.

### Exemplary Arrangements

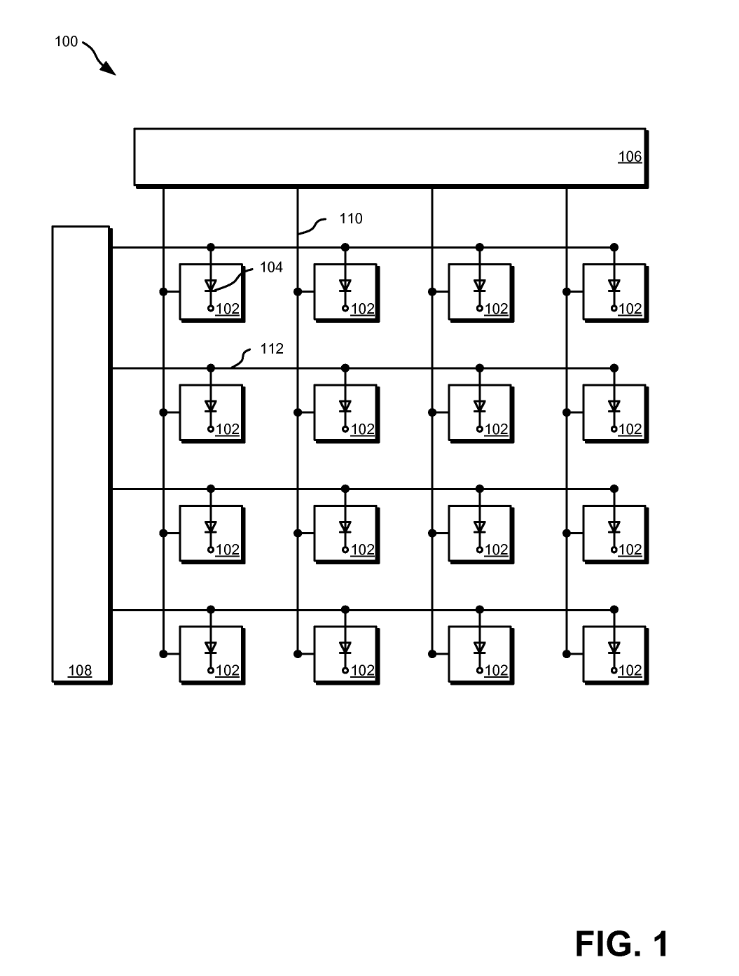

FIG. 1 is a diagram illustrating a pixel arrangement 100 that may be incorporated in a display device (not shown). The pixel arrangement 100 includes a plurality of pixels 102. Each of the pixels 102 may include an illumination device 104. Each illumination device 104 may be an organic light-emitting diode (OLED), a light-emitting diode (LED), or other suitable light illuminating device. The pixel arrangement 100 further includes driver circuits 106 and 108. The driver circuit 106 is coupled to the pixels 102 by way of column conductors 110. The driver circuit 108 is coupled to the pixels 102 by way of row conductors 112.

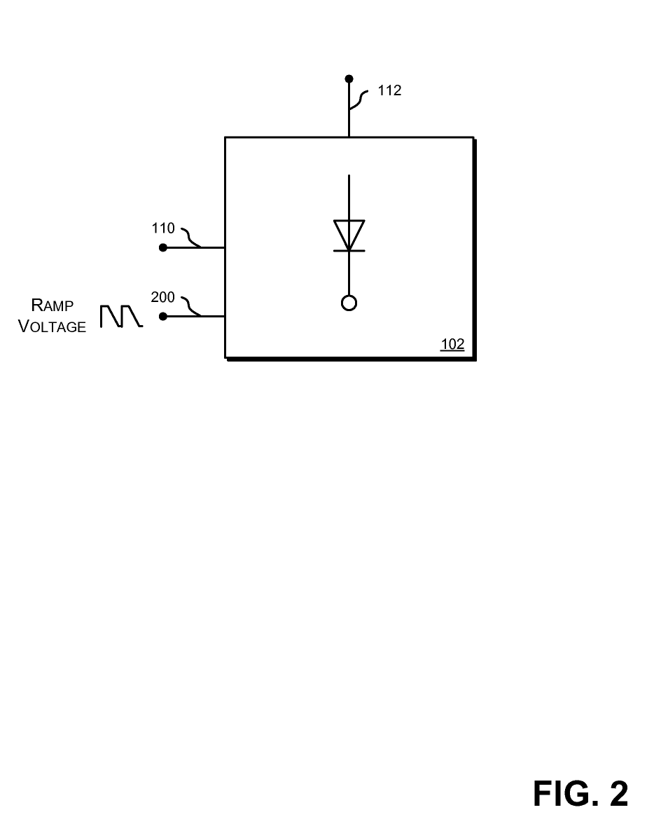

FIG. 2 illustrates a larger view of one of the pixels 102 illustrated in FIG. 1. As is shown, the pixel 102 may also receive a ramp voltage. The ramp voltage at least partially influences the luminance level of the pixel 102. The luminance level of the pixel 102 may be directly related to the frequency of the ramp voltage signal. A higher frequency ramp voltage signal generally increases the luminance level of the pixel 102, where a low frequency ramp voltage signal may decrease the luminance level of the pixel 102.

Pixels are generally square, as shown in FIG. 1, but can be any shape such as rectangular, round, oval, hexagonal, polygonal, or any other shape. If the display incorporating the pixel arrangement is a color display, the pixels 102 can also be subpixels organized in groups, each group corresponding to a pixel. The subpixels in a group should include a number (e.g., 3) of subpixels each occupying a portion of the area designated for the corresponding pixel. For example, if each pixel is in the shape of a square, the subpixels are generally as high as the pixel, but only a fraction (e.g., ⅓) of the width of the square. Subpixels may be identically sized or shaped, or they may have different sizes and shapes. In the following discussion, the reference of a pixel can mean both a pixel or subpixel. Moreover, such pixels may be color or white light producing pixels.

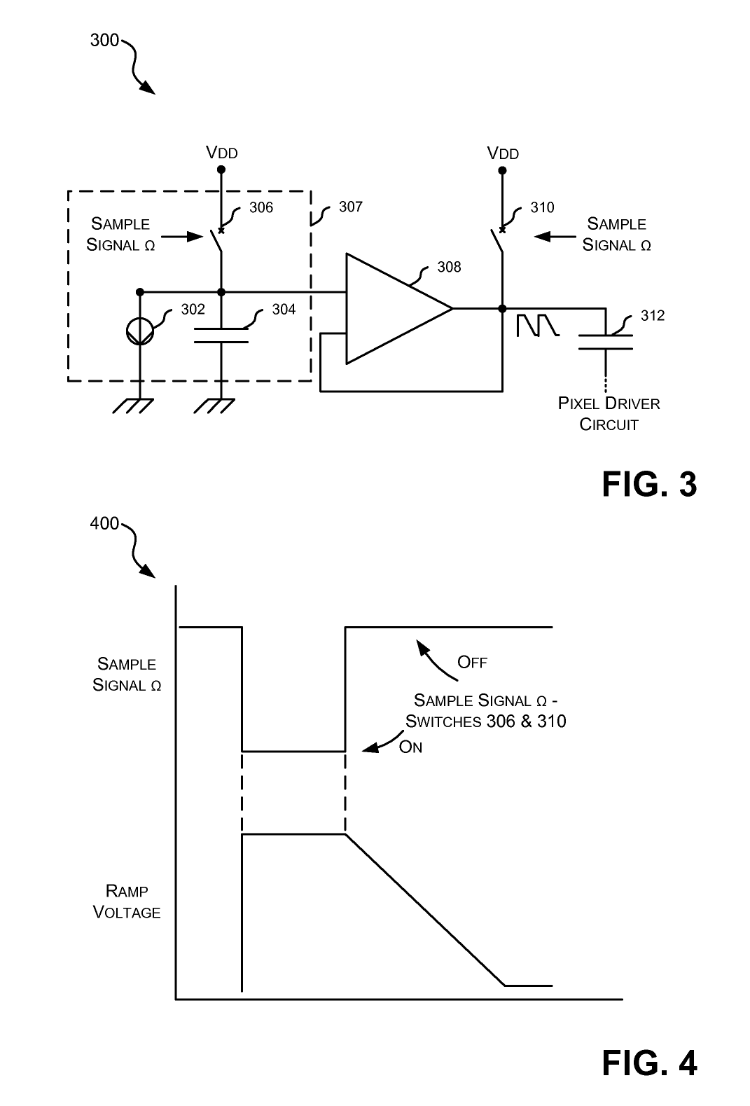

FIG. 3 illustrates an exemplary ramp voltage generating circuit 300. The exemplary ramp voltage generating circuit may be used in conjunction with the implementations illustrated in FIGS. 1 and 2. However, the generating circuit 300 may be used in connection with many other illuminating driving circuits, display devices, and other related technologies.

The generating circuit 300 may include a current source 302, a capacitor 304 and a switch 306. The combination of the a current source 302, a capacitor 304 and a switch 306 may be referred to as a ramp generating circuit arrangement 307. The current source 302 is coupled to a first input of an operational transconductance amplifier (OTA) 308. Furthermore, the current source 302 is coupled to a terminal of the capacitor 304 and to a terminal of the switch 306. Another terminal of the switch 306 is interfaced with voltage V_{DD}. The OTA 308 has a second input that is coupled to a second switch 310. The second switch 310 is also interfaced with V_{DD}. The OTA 308 outputs a ramp voltage when a sample signal Ω closes the switches 306 and 310. An (N-channel Metal-oxide Semiconductor) NMOS transistor associated with the OTA 308 may source a capacitor 312 associated with a pixel driver circuit. The NMOS transistor may have a width to length ratio of millimeters to micrometers. Further operational aspects of the generating circuit 300 are described in connection with FIG. 4. In one implementation, the switch 310 is a large a (P-channel Metal-oxide Semiconductor) PMOS transistor. The large PMOS switch may have a width to length ratio of millimeters to micrometers. Other width to length ratios are also possible (e.g., a width to length ratio of micrometers to nanometers). Other width to length ratios are also possible (e.g., a width to length ratio of micrometers to nanometers). Also, in one implementation, the OTA 308 is a low power consumption operational amplifier.

FIG. 4 is a signal diagram that may be used to describe the operation of the generating circuit 300 illustrated in FIG. 3. When the sample signal Ω is high, both switches 306 and 310 are in the open state. At this time, a ramp voltage is not being provided by the generating circuit 300, or the generating circuit 300 is providing a ramped-down portion of a ramp voltage. When the sample signal Ω transitions to a low level, the switch 306 toggles to a closed state. Also, this transition to the low level of the sample signal Ω closes the switch 310. The ramp voltage is generated when the switches 306 and 310 are in the closed state. The ramp voltage generated when the switches 306 and 310 are in the closed state may be at or near a maximum predetermined ramp voltage level. The maximum ramp voltage level is determined by V_{DD}.

When the sample signal Ω transitions back to a high state, the switches 306 and 310 are switched to an open state. This switching enables the capacitor 304 to discharge. This discharge is shown by the linear reduction in the ramp voltage shown in FIG. 4. The ramped down portion of the ramp voltage may also have non-linear attributes as well. At generally the same time, the capacitor 312 is sourced by the NMOS transistor of the OTA 308. The large NMOS transistor may have a width to length ratio of millimeters to micrometers. Other width to length ratios are also possible (e.g., a width to length ratio of micrometers to nanometers).

The sample signal Ω may be a pulsed, frequency variable, clock signal. A higher frequency sample signal Ω may produce ramp voltage signals at a higher frequency. Higher frequency ramp voltage signals may increase the brightness of the pixels interfaced with the generating circuit 300, where lower frequency ramp voltage signals may decrease the brightness of the pixels. A control unit (not shown) interfaced with the generating circuit 300 may control the prevailing frequency of the sample signal Ω in order to effectively vary the illumination level of pixels coupled to the to the circuit 300.

The use of the large switch 310 may pull-up the ramp voltage quickly. Nonetheless, the power consumption of the generating circuit 300 remains low. The low power consumption is further achieved through the use of a low power consuming NMOS device associated with the OTA 308.

### Procedure

The following discussion describes procedures that may be realized utilizing the previously described implementations. In one implementation, the illustrated and described procedures may be used to generate a ramp voltage signal. The ramp voltage signal may be generated by the exemplary ramp voltage generating circuit 300, and the ramp voltage signal may be supplied to a display device that incorporates a plurality of pixels.

The procedures are illustrated as a collection of blocks in a logical flow diagram, which represent a sequence of operations that can be implemented in hardware, software, or a combination thereof. In the context of software, the blocks represent computer-executable instructions that, when executed by one or more processors, perform the recited operations. Generally, computer-executable instructions include routines, programs, objects, components, data structures, and the like that perform particular functions or implement particular abstract data types. The order in which the operations are described is not intended to be construed as a limitation, and any number of the described blocks can be combined in any order and/or in parallel to implement the process.

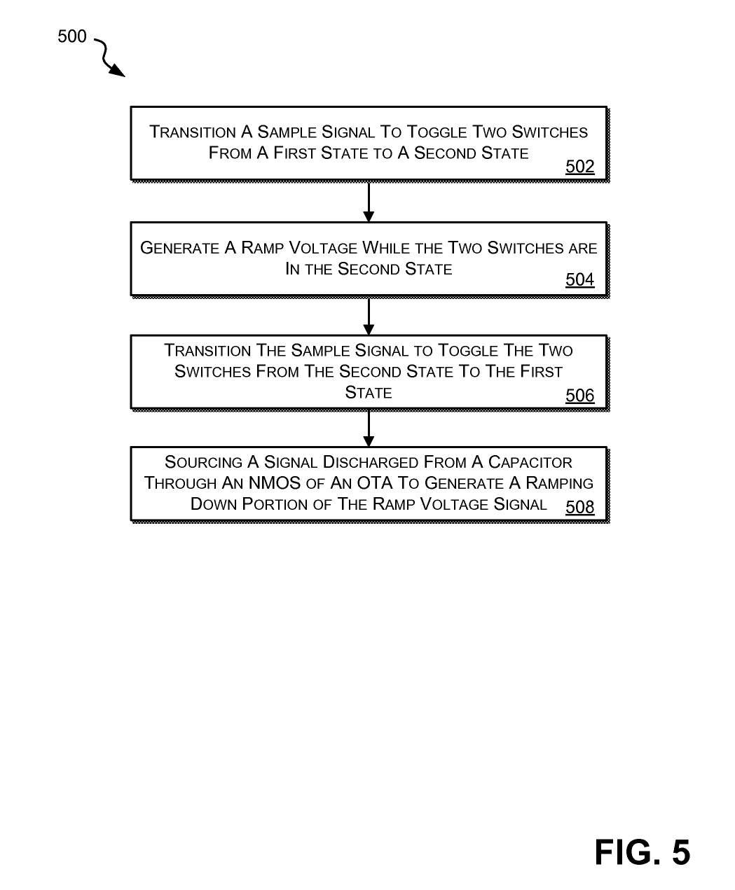

FIG. 5 illustrates a flow diagram 500 that include a number of operations enabling the generation of a ramp voltage, while maintaining a low power consumption signature. At block 502, a sample signal is transitioned from a first state to a second state to toggle two switches. In one implementation, the sample signal toggles from a high state to a low state to toggle the two switches to a closed state. At block 504, a ramp voltage is generated while the two switches are in the second state. The leading edge of the ramp voltage is pulled high quickly by way of a large PMOS transistor that is one of the two switches.

At block 506, the sample signal is transitioned from a second state to a first state to toggle the two switches. In one implementation, the sample signal toggles from a low state to a high state to toggle the two switches to an open state. At block 508, a capacitor is discharged to generate a ramping down portion of the ramp voltage. Acts 502-508 may be repeated to generate a plurality of ramped voltage signals.

### Computing System for Supporting and Making Use of a Ramp Voltage

The generation of a ramp voltage signal may be at least in part implemented in software executing and/or circuitry associated with a stationary or mobile computing system that utilizes a ramp voltage generator circuit 300 of the type illustrated in FIG. 3. For example, the ramp voltage generator circuit 300 may be incorporated in a display device (e.g., an output device) and used to generate a ramp voltage signal to effectuate illumination of pixels belonging to the display device.

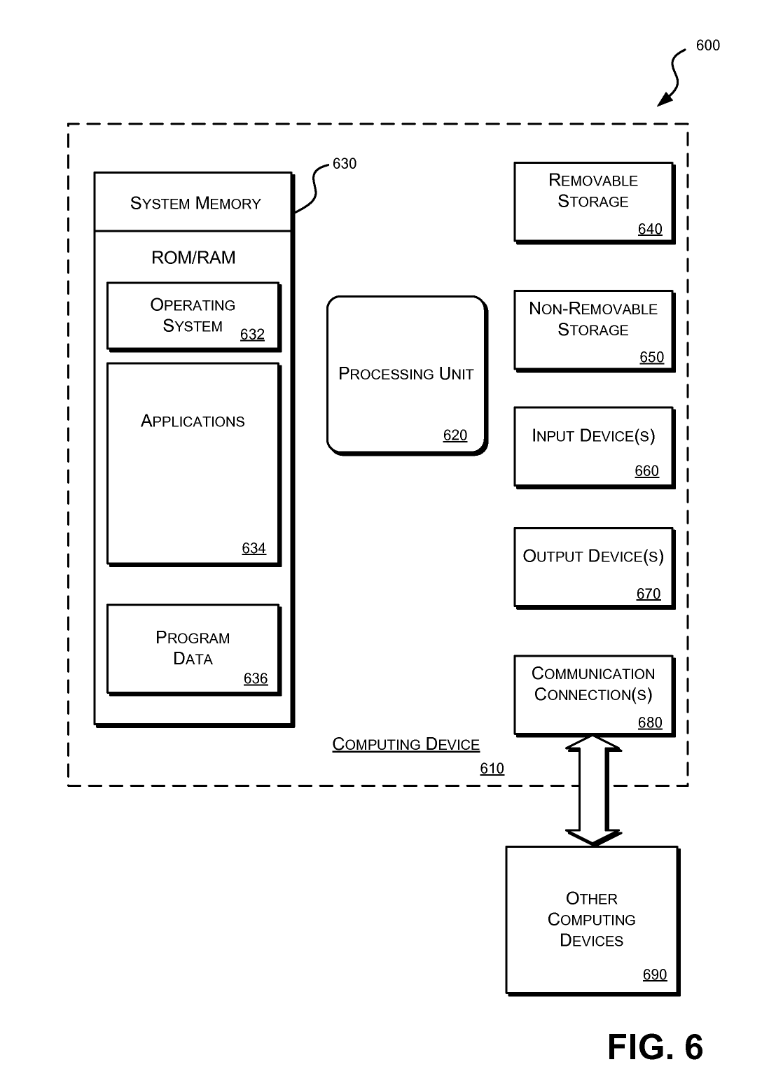

Referring to FIG. 6, an exemplary operating environment 600 includes a computing device, such as computing device 610. In a basic configuration, computing device 610 may include a stationary computing device or a mobile computing device. Computing device 610 typically includes at least one processing unit 620 and system memory 630. Depending on the exact configuration and type of computing device, system memory 630 may be volatile (such as RAM), non-volatile (such as ROM, flash memory, and the like) or some combination of the two. System memory 630 typically includes operating system 632, one or more applications 634, and may include program data 636.

Computing device 610 may also have additional features or functionality. For example, computing device 610 may also include additional data storage devices (removable and/or non-removable) such as, for example, magnetic disks, optical disks, tape, interchangeable nonvolatile memory devices, etc. Such additional storage is illustrated in FIG. 6 by removable storage 640 and non-removable storage 650. Computer storage media may include volatile and non-volatile, removable and non-removable media implemented in any method or technology for storage of information, such as computer readable instructions, data structures, program modules or other data. System memory 630, removable storage 640 and non-removable storage 650 are all examples of computer storage media. Computer storage media includes, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, nonvolatile memory cards, or any other medium which can be used to store the desired information and which can be accessed by computing device 610. Any such computer storage media may be part of device 610. Computing device 610 may also have input device(s) 660 such as a keyboard, which may be operated according to an embodiment of a keyboard scan disclosed herein, mouse, pen, voice input device, touch input device, etc. Output device(s) 670 such as a display device, speakers, printer, etc. may also be included.

Computing device 610 also contains communication connection(s) 680 that allow the device to communicate with other computing devices 690, such as over a network or a wireless network. Communication connection(s) 680 is an example of communication media. Communication media typically embodies computer readable instructions, data structures, program modules or other data in a modulated data signal such as a carrier wave or other transport mechanism and includes any information delivery media. The term “modulated data signal” may include a signal that has one or more of its characteristics set or changed in such a manner as to encode information in the signal. By way of example, and not limitation, communication media may include wired media such as a wired network or direct-wired connection, and wireless media such as acoustic, RF, infrared and other wireless media. The term computer readable media as used herein includes both storage media and communication media.

### CONCLUSION

Although the subject matter has been described in language specific to structural features and/or methodological acts, it is to be understood that the subject matter defined in the appended claims is not necessarily limited to the specific features or acts described. Rather, the specific features and acts are disclosed as example forms of implementing the claims.

What is claimed is:

1. A apparatus, comprising:
a first switch and a second switch toggleable with a common control signal; and
an operational amplifier coupled to the first and second switches, the operational amplifier to output a ramp voltage when the first and second switches are in a closed state.

2. The apparatus according to claim 1, wherein the ramp voltage output from the operational amplifier is at a substantially maximum level when the first and second switches are in closed state.

3. The apparatus according to claim 1, wherein the ramp voltage is ramped down when the first and second switches are toggled from a closed state to an open state.

4. The apparatus according to claim 1, wherein the common control signal is a pulsed clock signal.

5. The apparatus according to claim 1, wherein the first switch is coupled to a capacitor, the capacitor being charged when the first switch is in the closed state, the capacitor to discharge when the first switch is in an open state.

6. The apparatus according to claim 5, wherein the operational amplifier includes an (N-channel Metal-oxide Semiconductor) NMOS transistor, a current from a capacitor associated with a driver circuit being sourced through the NMOS transistor when at least the first switch is in the open state.

7. The apparatus according to claim 1, wherein the second switch is a (P-channel Metal-oxide Semiconductor) PMOS transistor having a width to length ratio of millimeters to micrometers.

8. The apparatus according to claim 1, wherein the operational amplifier includes an (N-channel Metal-oxide Semiconductor) NMOS transistor having a width to length radio of millimeters to micrometers.

9. A method, comprising:
transitioning a sample signal to toggle two switches from a first state to a second state;
generating a ramp voltage while the two switches are in the second state, the generated ramp voltage having a near maximum level while the two switches are in the second state;
transitioning the sample signal to toggle the two switches from the second state to the first state; and
generating a ramped down portion of the ramp signal at least a portion of the time that the two switches are in the first state.

10. The method according to claim 9, further comprising discharging a capacitor to produce the ramped down portion of the ramp signal.

11. The method according to claim 9, wherein at least one of the two switches is a (P-channel Metal-oxide Semiconductor) PMOS transistor.

12. The method according to claim 11, wherein the PMOS transistor has a width to length ratio of millimeters to micrometers.

13. The method according to claim 9, wherein generating the ramped down portion of the ramp signal includes discharging a capacitor through an operational amplifier.

14. The method according to claim 9, further comprising pulling up a leading edge of the ramp voltage with a (P-channel Metal-oxide Semiconductor) PMOS transistor, the PMOS transistor being implemented as one of the two switches.

15. A system including a ramp voltage generating circuit, the circuit comprising:
a (P-channel Metal-oxide Semiconductor) PMOS transistor to receive a sample signal; and
a ramp generating circuit arrangement coupled to the PMOS transistor, the ramp generating circuit to generate a ramp voltage, a leading edge of the ramp voltage pulled up by the PMOS transistor when the PMOS transistor is in an on state.

16. The ramp voltage generating circuit according to claim 15, wherein the ramp generating circuit includes a switch to receive the sample signal.

17. The ramp voltage generating circuit according to claim 16, wherein the switch is coupled to a capacitor, the capacitor being charged when the switch is in a closed state, the capacitor to discharge when the switch is in an open state.

18. The ramp voltage generating circuit according to claim 17, further comprising an operational amplifier coupled at least to the PMOS transistor and the capacitor.

19. The ramp voltage generating circuit according to claim 15, further comprising an operational amplifier coupled to the PMOS transistor and the ramp generating circuit arrangement.
